(19) United States
(12) Patent Application Publication
(10) Pub. No.: US 2026/0158670 A1
(43) Pub. Date: Jun. 11, 2026

(54) ASSEMBLY EQUIPMENT AND MANUFACTURING PROCESS FOR VAPOR CHAMBER

(71) Applicant: Shenzhen VC Thermal Technology Co., Ltd., Shenzhen (CN)

(72) Inventors: Xiaoqing LI, Shenzhen, Guangdong (CN); Jianwei LI, Shenzhen, Guangdong (CN)

(21) Appl. No.: 19/181,565

(22) Filed: Apr. 17, 2025

(30) Foreign Application Priority Data
Jun. 28, 2024 (CN) 202410860948.8

(51) Int. Cl. B25J 11/00; B25J 9/00; B25J 9/16; B25J 21/00; F28F 21/08

(52) U.S. Cl. CPC B25J 11/005; B25J 9/0009; B25J 9/1687; B25J 21/00; F28F 21/085; F28F 2275/06; F28F 2280/10

(57) ABSTRACT

An assembly equipment and a manufacturing process for a vapor chamber include a vacuum chamber configured to provide a vacuum environment; a turnplate rotatably disposed inside the vacuum chamber and is provided with an upper cover loading station, a water injection station, a lower cover loading station, a welding station, and an unloading station; an upper cover loading device installed inside the vacuum chamber and configured to move an upper cover welded with a copper mesh onto the turnplate; a water injection device configured to inject water into the upper cover; a lower cover loading device configured to move a lower cover onto the upper cover; a welding head configured to weld the upper cover and the lower cover; and an unloading device configured to unload the manufactured vapor chamber.

### CROSS-REFERENCE TO RELATED APPLICATION

The present application is based on and claims the priority benefits of China application No. 202410860948.8, filed on Jun. 28, 2024. The entirety of China application No. 202410860948.8 is hereby incorporated by reference herein and made a part of this specification.

### TECHNICAL FIELD

The present application relates to a production technique of vapor chambers, and, in particular, to an assembly equipment and a manufacturing process for a vapor chamber.

### BACKGROUND

As an efficient thermal management component, vapor chambers are widely used in electronic devices, LED lighting, telecommunications base stations, and other applications.

The existing assembly equipment first stamps the raw material into an upper cover and a lower cover through a stamping process. After cutting a mesh with a mesh-cutting and spot-welding device, the mesh is spot-welded onto the upper cover. Following the spot-welding, an edge-sealing process is carried out to assemble and weld the upper cover and the lower cover together. After the edge sealing process, a copper tube is inserted into an expanded hole at the rat-tail section and sealed through an adhesive dispensing process by a tube insertion and adhesive dispensing device. Subsequently, a first degassing device performs water injection and vacuum extraction until a required vacuum value is achieved, after which the copper tube is crimped for sealing. Then a second degassing device performs a secondary degassing and laser welding for sealing. Finally, the rat-tail section and excess copper tube sections are cut off.

The above related technologies involve overly complex processes, requiring substantial investments in both human and material resources, along with prohibitively high equipment costs.

### SUMMARY

The object of the present application is to provide an assembly equipment and a manufacturing process for a vapor chamber, which may reduce production steps, lower investment costs of the assembly equipment, and decrease labor and material inputs.

In a first aspect, the present application provides an assembly equipment for a vapor chamber, including:
a vacuum chamber configured to provide a vacuum environment;
a turnplate rotatably disposed inside the vacuum chamber, the turnplate is provided with an upper cover loading station, a water injection station, a lower cover loading station, a welding station, and an unloading station;
an upper cover loading device installed inside the vacuum chamber, the upper cover loading device corresponds in position to the upper cover loading station and is configured to move an upper cover welded with a copper mesh onto the turnplate;
a water injection device installed inside the vacuum chamber, the water injection device corresponds in position to the water injection station and is configured to inject water into the upper cover;
a lower cover loading device installed inside the vacuum chamber, the lower cover loading device corresponds in position to the lower cover loading station and is configured to move a lower cover onto the upper cover;
a welding head installed inside the vacuum chamber, the welding head corresponds in position to the welding station and is configured to weld the upper cover and the lower cover; and
an unloading device installed inside the vacuum chamber, the unloading device corresponds in position to the unloading station and is configured to unload the manufactured vapor chamber.

By adopting the aforementioned technical solution, the upper cover loading device, the water injection device, the lower cover loading device, the welding head, and the unloading device are all installed within the vacuum chamber, so that it is unnecessary to evacuating the space between the upper cover and the lower cover after welding them together. Additionally, the upper cover may be filled with water before welding the upper cover and the lower cover, therefore, a rat-tail section on the upper cover and the lower cover is not required any more and a copper tube is not required any more for evacuation and water injection, such that the process of cutting off the rat-tail section and the copper tube is emitted, which optimizes the entire manufacturing process for the vapor chamber and is convenient for manufacturing of a vapor chamber, reduces investment costs in the assembly equipment, and decreases inputs of manpower and material resources.

Optionally, the assembly equipment for the vapor chamber further includes a compression device, the compression device is configured to press the upper cover and the lower cover together, and the compression device includes a first telescopic part, a mounting plate, a link rod, a first pressure plate, and a second pressure plate, the first pressure plate and the second pressure plate are both fixed to the mounting plate via the link rod, the first pressure plate is annular and is sleeved on the second pressure plate with an annular gap between the first pressure plate and the second pressure plate, the annular gap is adapted to the vapor chamber, and the welding head is mounted on the mounting plate and configured to weld the upper cover and the lower cover through the annular gap.

By adopting the above technical solution, the upper cover and the lower cover are pressed together by the compression device firstly and then welded, which ensures the welding quality between them, thereby guaranteeing the quality of the vapor chamber.

Optionally, the assembly equipment for the vapor chamber further includes a plurality of material holders for placing the upper cover, the plurality of material holders are all fixedly connected to the turnplate, and the upper cover loading station, the water injection station, the lower cover loading station, the welding station, and the unloading station each are provided with one of the plurality of material holders.

By adopting the above technical solution, the material holder at every workstation may hold an upper cover, that is, all the workstations may operate simultaneously. This eliminates the need to complete processing of one vapor chamber before starting another, allowing continuous assembly of multiple vapor chambers, thereby increasing the efficiency of the assembly equipment for the vapor chamber.

Optionally, each of the plurality of material holders is fixedly connected with a plurality of positioning blocks, and the plurality of positioning blocks are circumferentially distributed and are configured to limit a movement of the upper cover.

By adopting the above technical solution, the positioning blocks are provided to restrict the movement of the upper cover, thereby reducing displacement of the upper cover during rotation of the turntable.

Optionally, surfaces of the plurality of positioning blocks facing each other are formed with arc-shaped surfaces.

By adopting the above technical solution, even if the upper cover deviates, it may be guided back to its original position through the arc-shaped surface, which ensures positional stability of the upper cover, so as to manufacture a vapor chamber with higher quality.

Optionally, the upper cover loading device includes a placement plate fixedly installed in the vacuum chamber, a plurality of positioning posts fixedly connected with the placement plate, a second telescopic part fixedly connected with the placement plate, and a first robotic arm mounted in the vacuum chamber, the plurality of positioning posts are circumferentially distributed on the placement plate and configured to limit a movement of the upper cover, the second telescopic part is configured to lift the upper cover upward, and the first robotic arm is configured to transport the upper cover to the upper cover loading station.

By adopting the above technical solution, the second telescopic part is provided, so that when the uppermost upper cover is removed, the second telescopic part extends to move the next upper cover to a predetermined position, thereby facilitating retrieval of the upper cover by the first robotic arm.

Optionally, the first robotic arm includes a frame fixedly installed in the vacuum chamber, a linear guide rail fixedly installed on the frame, a third telescopic part fixedly connected to an output end of the linear guide rail, and a suction cup, and the suction cup is fixedly attached to the third telescopic part and is configured to adsorb the upper cover.

By adopting the above technical solution, the linear guide rail moves the third telescopic part, which cooperates with the suction cup to adsorb the upper cover, to move the upper cover. This configuration features a simple structure and linear motion, thereby ensuring stable operation of the first robotic arm with reduced failure probability.

Optionally, the unloading device includes a second robotic arm and an unloading base, the unloading base is configured with a plurality of slots for accommodating the vapor chamber, and the second robotic arm is fixedly mounted inside the vacuum chamber and is configured to transfer the vapor chamber into a respective one of the plurality of slots.

By adopting the above technical solution, the second robotic arm transfers the manufactured vapor chambers to the slots for storage, so as to achieve a continuous operation of the assembly equipment for the vapor chamber without requiring intermittent pauses between individual unit productions.

In a second aspect, the present application provides a manufacturing process for a vapor chamber, including:
S1: manufacturing the upper cover and the lower cover;
S2: manufacturing a copper mesh and welding the copper mesh into the upper cover;
S3: placing a plurality of upper covers welded with copper meshes onto the upper cover loading device;
S4: evacuating the vacuum chamber to create the vacuum environment;
S5: transferring one of the plurality of upper covers welded with the copper meshes on the loading device to the water injection station, to fill the one of the plurality of upper covers with water;
S6: moving the one of the plurality of upper covers to the lower cover loading station, then moving the lower cover onto the one of the plurality of upper covers to be in contact with the one of the plurality of upper covers;
S7: welding the one of the plurality of upper covers and the lower covers in contact; and
S8: unloading a manufactured vapor chamber.

By adopting the above technical solution, the upper cover and the lower cover are placed within the vacuum chamber firstly, so that it is unnecessary to evacuate the space between the upper cover and the lower cover after welding them together. Additionally, the upper cover is firstly filled with water, so that it is unnecessary to fill the upper cover and the lower cover with water after welding them together. Therefore, no rat-tail section and no copper tube is required on the upper cover and the lower cover, and thus no process for cutting off the rat-tail section and the copper pipe is required, so as to simplify the manufacturing process for a vapor chamber, thereby facilitating the manufacturing of a vapor chamber, which reduces labor and material resource inputs.

In summary, the present application includes at least one of the following beneficial technical effects:
1. The upper cover loading device, the water injection device, the lower cover loading device, the welding head, and the unloading device are all installed within the vacuum chamber, so that it is unnecessary to evacuating the space between the upper cover and the lower cover after welding them together. Additionally, the upper cover may be filled with water before welding the upper cover and the lower cover, therefore, a rat-tail section on the upper cover and the lower cover is not required anymore and a copper tube is not required any more for evacuation and water injection, such that the process of cutting off the rat-tail section and the copper tube is emitted, which optimizes the entire manufacturing process for the vapor chamber and is convenient for manufacturing of a vapor chamber, reduces investment costs in the assembly equipment, and decreases inputs of manpower and material resources.
2. The upper cover and the lower cover are pressed together by the compression device firstly and then welded, which ensures the welding quality between them, thereby guaranteeing the quality of the vapor chamber.
3. The upper cover and the lower cover are placed within the vacuum chamber firstly, so that it is unnecessary to evacuate the space between the upper cover and the lower cover after welding them together. Additionally, the upper cover is firstly filled with water, so that it is unnecessary to fill the upper cover and the lower cover with water after welding them together. Therefore, no rat-tail section and no copper tube is required on the upper cover and the lower cover, and thus no process for cutting off the rat-tail section and the copper pipe is required, so as to simplify the manufacturing process for a vapor chamber, thereby facilitating the manufacturing of a vapor chamber, which reduces labor and material resource inputs.

### BRIEF DESCRIPTION OF THE DRAWINGS.

FIG. 1 is an overall structure view of an assembly equipment for a vapor chamber in an embodiment of the present application after opening a vacuum chamber.

FIG. 2 is a partial enlarged view of Part A in FIG. 1.

FIG. 3 is a partial enlarged view of Part B in FIG. 1.

FIG. 4 is a partial enlarged view of Part C in FIG. 1.

FIG. 5 is a partial enlarged view of Part D in FIG. 1.

FIG. 6 is a structure view of a compression device according to an embodiment of the present application.

FIG. 7 is a structure view for showing the mating relationship between the compression device and a material holder according to an embodiment of the present application.

### DETAILED DESCRIPTION

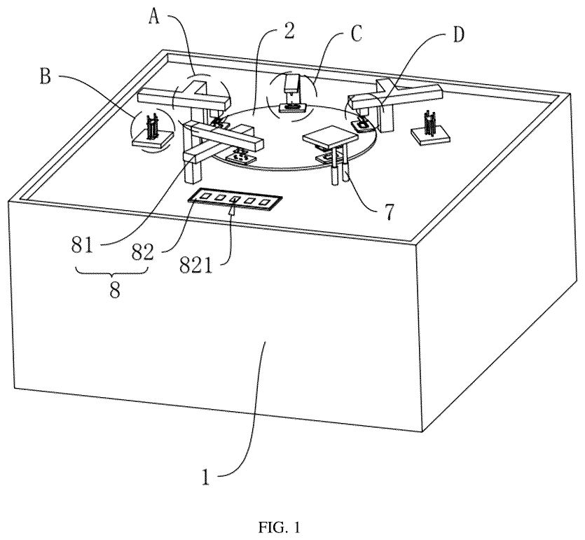

The present application is further described in detail below with reference to FIGS. 1-7.

### Embodiment 1

An assembly equipment for a vapor chamber, with reference to FIG. 1, includes a vacuum chamber 1 equipped with a vacuum pump configured to evacuate air from the vacuum chamber 1, thereby creating a vacuum environment within the vacuum chamber 1. A turnplate 2 is rotatably mounted within the vacuum chamber 1. In the present embodiment, the turnplate 2 is rotationally driven by an electric motor, which may be driven by other driving component in other embodiments.

The turnplate 2 is equipped with an upper cover loading station, a water injection station, a lower cover loading station, a welding station, and an unloading station. At the upper cover loading station, the upper cover 91 is mounted on the turnplate 2. The turnplate 2 rotates to carry the upper cover 91 to the water injection station. After the water injection, the turnplate 2 rotates to carry the upper cover 91 to the lower cover loading station, where the upper cover 91 contacts the lower cover 92. The turnplate 2 further rotates to carry the upper cover 91 and the lower cover 92 to the welding station, where the upper cover 91 and the lower cover 92 are welded together to form a finished vapor chamber. Finally, the turnplate rotates to the unloading station for unloading.

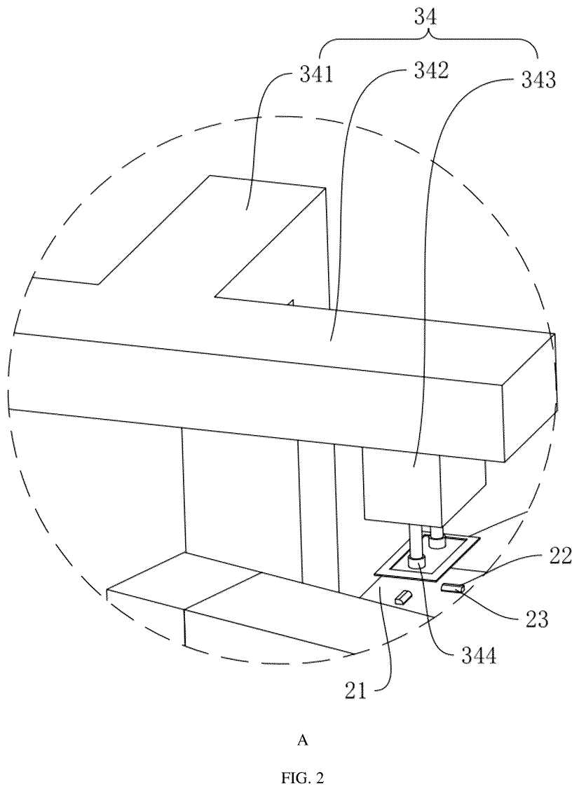

With reference to FIGS. 1 and 2, specifically, the turnplate 2 is fixedly connected with a plurality of material holders 21. Each of the upper cover loading station, the water injection station, the lower cover loading station, the welding station, and the unloading station is provided with one of the plurality of material holders 21. The material holder 21 is configured to accommodate the upper cover 91. During operation of the assembly equipment for the vapor chamber, each material holder 21 at every workstation may hold an upper cover 91, that is to say, all workstations may operate simultaneously. There is no need to complete the processing of one single vapor chamber before moving on to the next, namely multiple vapor chambers may be assembled continuously, thereby enhancing the efficiency of the assembly equipment for the vapor chamber.

Furthermore, each material holder 21 is provided with a plurality of positioning blocks 22, which are circumferentially distributed on the material holder 21. The upper cover 91 is placed among the plurality of positioning blocks 22. The plurality of positioning blocks 22 are configured to limit the movement of the upper cover 91, so as to minimize displacement of the upper cover 91 during rotation of the turnplate 2.

Additionally, the surfaces of the positioning blocks 22 facing each other are formed with arc-shaped surfaces 23. Specifically, when the upper cover 91 is placed among the positioning blocks 22, the surfaces of the positioning blocks 22 facing the upper cover 91 are configured with these arc-shaped surfaces 23. The upper cover 91 may be readjusted back to its original position by means of the arc-shaped surfaces 23, even if the upper cover 91 experiences positional deviation, which ensures consistent positioning of the upper cover 91, thereby enhancing the quality of the manufactured vapor chambers.

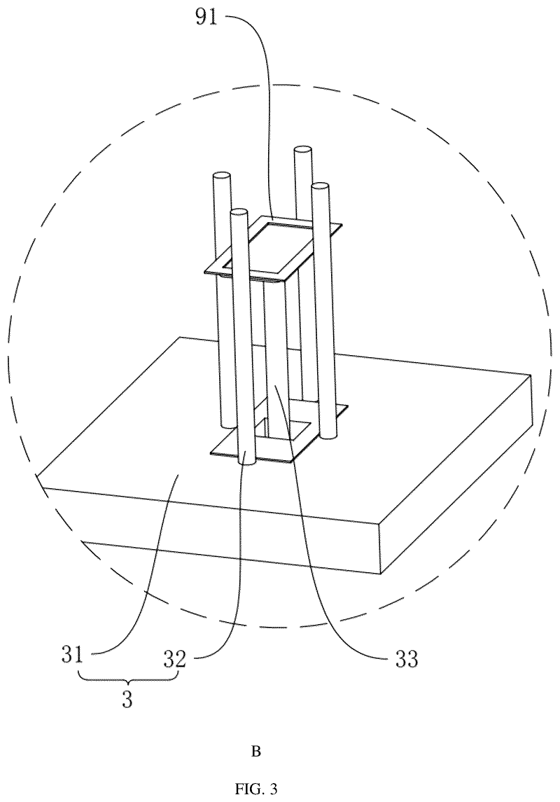

With reference to FIGS. 2 and 3, an upper cover loading device 3 is disposed adjacent to the upper cover loading station. The upper cover loading station transports the upper cover 91 onto the material holder 21 at the upper cover loading station. Specifically, the upper cover loading device 3 includes a placement plate 31 fixed near the upper cover loading station, a plurality of positioning posts 32 fixed on the placement plate 31 circumferentially, a second telescopic part 33, and a first robotic arm 34. The upper covers 91 welded with copper meshes are stacked among the positioning posts 32, so as to be limited by the positioning posts 32, which ensures consistent positioning of the upper covers 91. The first robotic arm 34, positioned near the placement plate 31, picks up the topmost upper cover 91 among the positioning posts 32 and transfers it to the material holder 21 at the upper cover loading station.

The second telescopic part 33 is fixed on the placement plate 31. When the topmost upper cover 91 is transported away, the second telescopic part 33 extends to push the remaining upper covers 91 upward, facilitating the transfer of the upper cover 91 by the first robotic arm 34. Specifically, a CCD automated vision imaging device is installed within the vacuum chamber 1. The CCD automated vision imaging device is electrically connected to the second telescopic part 33. When the topmost upper cover 91 reaches a predetermined position, the CCD automated vision imaging device controls the second telescopic part 33 to stop extending. In this embodiment, the second telescopic part 33 may be an electric telescopic rod, which may be other extendable component in other embodiments.

The first robotic arm 34 includes a frame 341 fixedly mounted within the vacuum chamber 1 adjacent to the upper cover loading station, a linear guide rail 342 fixedly connected to the frame 341, where one end of the linear guide rail is positioned above the placement plate 31 while the other end thereof is positioned above the material holder 21 at the upper cover loading station, a third telescopic part 343 fixedly connected to an output end of the linear guide rail 342, and a suction cup 344 fixedly attached to an end of the third telescopic part 343 away from the linear guide rail 342.

The linear guide rail 342 first moves the third telescopic part 343 to be above the placement plate 31. At this stage, the third telescopic part 343 extends, so that the suction cup 344 abuts against the upper cover 91. Once the suction cup 344 securely grips the upper cover 91, the third telescopic part 343 retracts, to remove the upper cover 91 from the zone limited by the positioning posts 32. Subsequently, the linear guide rail 342 transports the upper cover 91 to the upper cover loading station. The third telescopic part 343 then extends again to place the upper cover 91 onto the material holder 21. At this point, the suction cup 344 releases the upper cover 91, thereby completing the loading process for an upper cover. By repeating this procedure, a continuous loading is achieved.

Specifically, in the present embodiment, the third telescopic part 343 is configured as an electric telescopic rod, while the suction cup 344 is configured as an electronically controlled suction cup 344, to on-demand control the gripping of the upper cover 91 by the suction cup 344.

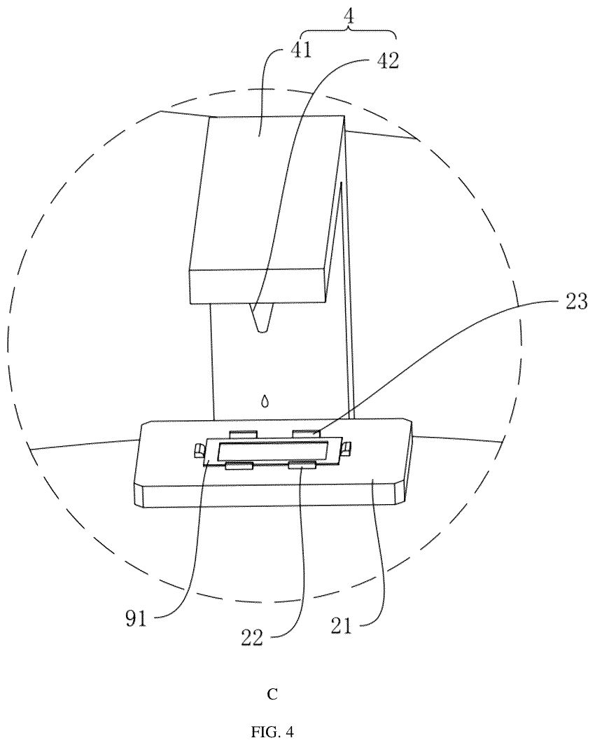

With reference to FIG. 4, a water injection device 4 is provided adjacent to the water injection station. The water injection device 4 is fixedly mounted within the vacuum chamber 1 and includes a support frame 41 fixedly arranged in the vacuum chamber 1, and a water injection pipe 42 fixedly connected to the support frame 41. One end of the water injection pipe 42 is positioned above the material holder 21 at the water injection station, while the other end thereof is connected to a water reservoir. The water injection pipe 42 is configured to deliver water from the water reservoir into the upper cover 91 at the water injection station, thereby completing the water injection of the upper cover 91.

Specifically, the water reservoir is equipped with a water pump. By controlling the activation and deactivation of the water pump, the water injection pipe 42 is regulated to inject water into the upper cover 91 or not. The water reservoir may be installed either inside or outside the vacuum chamber 1, so long as the vacuum degree of the vacuum chamber 1 is not influenced.

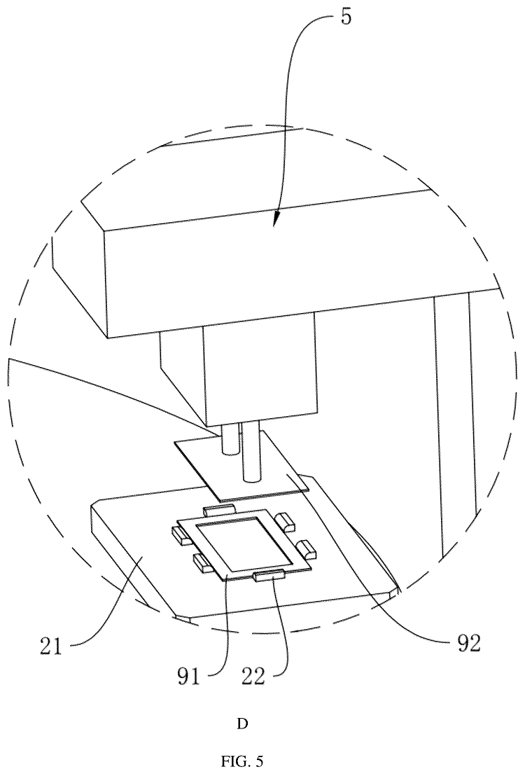

With reference to FIG. 5, a lower cover loading device 5 is disposed adjacent to the lower cover loading station. In the present embodiment, the lower cover loading device 5 has an identical structure to the upper cover loading device 3, that is, the lower cover loading device 5 includes an aforementioned first robotic arm 34, an aforementioned placement plate 31, aforementioned positioning posts 32, an aforementioned second telescopic part 33, and an aforementioned CCD automated vision imaging device. The operational principle of the lower cover loading device 5 is the same as that of the upper cover loading device 3, and thus redundant descriptions are omitted here. After water injection of the upper cover 91 is completed, the turnplate 2 rotates to transport the upper cover 91 to the lower cover loading station. The lower cover loading device 5 then delivers the lower cover 92 to be above the upper cover 91, so as to abut against the upper cover 91. The lower cover 92 is also limited by the positioning blocks 22, thereby guaranteeing fixed relative positioning between the upper cover 91 and lower cover 92, and thus avoiding the positional deviation between the upper cover 91 and the lower cover 92.

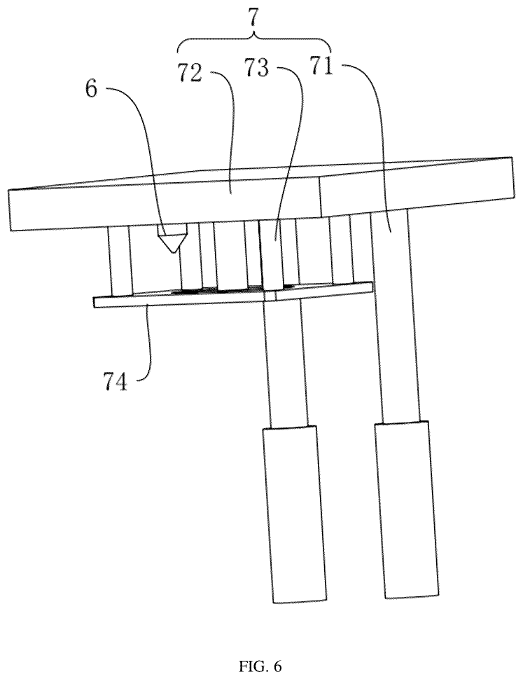

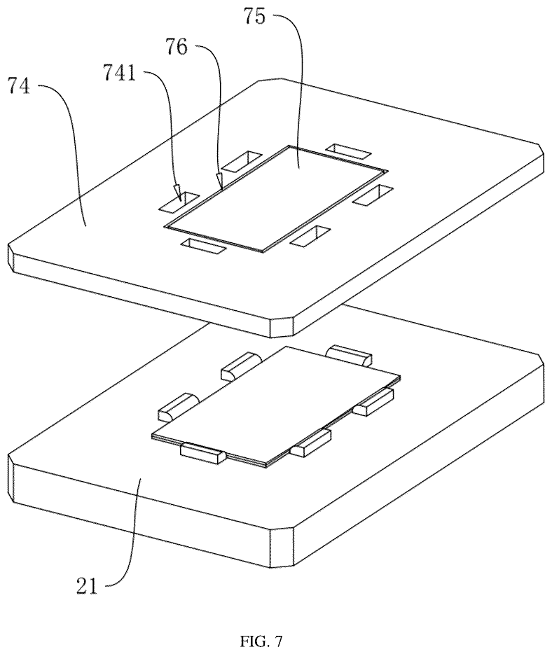

With reference to FIGS. 6 and 7, a welding head 6 is disposed adjacent to the welding station. The welding head 6 is configured to weld the upper cover 91 and the lower cover 92 together, thereby completing the manufacturing of the vapor chamber.

Furthermore, a compression device 7 is disposed adjacent to the welding station. The compression device 7 is configured to compress the upper cover 91 and the lower cover 92 together, thereby ensuring the welding quality.

The compression device 7 includes a first telescopic part 71 fixedly mounted within the vacuum chamber 1 near the welding station, a mounting plate 72 fixedly connected to a top end of the first telescopic part 71, link rods 73, a first pressure plate 74, and a second pressure plate 75. Both the first pressure plate 74 and the second pressure plate 75 are fixedly connected to the mounting plate 72 via the link rods 73. The first pressure plate 74 is annular and sleeved on the second pressure plate 75 with an annular gap 76 between them. The annular gap 76 is adapted to the vapor chamber. The welding head 6 is installed on the mounting plate 72 and is configured to weld the upper cover 91 and the lower cover 92 through the annular gap 76. In the present embodiment, the first telescopic part 71 is configured as an electric telescopic rod.

A plurality of through holes 741 are defined on the first pressure plate 74. The plurality of through holes 741 are arranged one-to-one corresponding to the plurality of positioning blocks 22, for the positioning blocks 22 to be inserted into.

Specifically, the welding head 6 is configured as a laser welding head 6. The welding head 6 is slidably arranged on the mounting plate 72, and a sliding path of the welding head 6 on the mounting plate 72 may be controlled through a control terminal. The sliding path is adapted to the annular gap 76, so that laser emitted by the welding head 6 passes through the annular gap 76, to weld the upper cover 91 and the lower cover 92.

An unloading device 8 is disposed near the unloading station, and the manufactured vapor chamber is unloaded by the unloading device 8.

The unloading device 8 includes a second robotic arm 81 and an unloading base 82. The unloading base 82 is fixedly installed inside the vacuum chamber 1 near the unloading station. A plurality of slots 821 are defined on the unloading base 82 for accommodating the vapor chambers. The second robotic arm 81 is fixedly disposed inside the vacuum chamber 1 near the unloading base 82. The second robotic arm 81 is configured to move the vapor chamber at the unloading station into the slot 821. In this embodiment, the second robotic arm 81 may be a robotic arm capable of three-dimensional movement, which is convenient for moving the vapor chamber.

The implementation principle of the present embodiment of the present application is as follows. First, the upper cover 91 welded with the copper mesh is moved to the material holder 21 through the upper cover loading device 3. At this time, the turnplate 2 rotates, to drive the upper cover 91 to move to the water injection station. The water injection pipe 42 injects water into the upper cover 91. After water injection is completed, the turnplate 2 rotates again, to drive the upper cover 91 to move to the lower cover loading station. The lower cover loading device 5 installs the lower cover 92 on the upper cover 91, so that the upper cover 91 is in contact with the lower cover 92. Then the turnplate 2 rotates again, to move the upper cover 91 and the lower cover 92 to the welding position, where the upper cover 91 and the lower cover 92 are compressed together by the first pressure plate 74 and the second pressure plate 75, and the welded by the welding head 6, thereby completing the manufacturing of the vapor chamber. Finally, the turnplate 2 rotates to the unloading station, and the second robotic arm 81 moves the vapor chamber into the slot 821 for storage.

### Embodiment 2

A manufacturing process for a vapor chamber, including:
S1. manufacturing an upper cover 91 and a lower cover 92;
S2. manufacturing a copper mesh and welding it into the upper cover 91;
S3. placing a plurality of upper covers 91 welded with copper meshes onto the upper cover loading device 3;
S4. evacuating the vacuum chamber 1 to create a vacuum environment;
S5. moving the upper cover 91 at the upper cover loading device 3 to the water injection station, to inject water into the upper cover 91;
S6. moving the upper cover 91 injected with water to the lower cover loading station, and moving the lower cover 92 onto the upper cover 91 to be in contact with the upper cover 91;
S7. welding the upper cover 91 and the lower cover 92 in contact with each other; and
S8. unloading the manufactured vapor chamber.

The above are the preferred embodiments of the present application, which are not intended to limit the protection scope of the present application. Therefore, all equivalent changes made according to the structure, shape and principle of the present application should be covered within the protection scope of the present application.

### LIST OF REFERENCE SIGNS

1 vacuum chamber
2 turnplate
21 material holder
22 positioning block
23 arc-shaped surface
3 upper cover loading device
31 placement plate
32 positioning post
33 second telescopic part
34 first robotic art
341 frame
342 linear guide rail
343 third telescopic part
344 suction cup
4 water injection device
41 support frame
42 water injection pipe
5 lower cover loading device
6 welding head
7 compression device
71 first telescopic part
72 mounting plate
73 link rod
74 first pressure plate
741 through hole
75 second pressure plate
76 annular gap
8 unloading device
81 second robotic arm
82 unloading base
821 slot
91 upper cover
92 lower cover

What is claimed is:

1. An assembly equipment for a vapor chamber, comprising:
a vacuum chamber configured to provide a vacuum environment;
a turnplate rotatably disposed inside the vacuum chamber, wherein the turnplate is provided with an upper cover loading station, a water injection station, a lower cover loading station, a welding station, and an unloading station;
an upper cover loading device installed inside the vacuum chamber, the upper cover loading device corresponds in position to the upper cover loading station and is configured to move an upper cover welded with a copper mesh onto the turnplate;
a water injection device installed inside the vacuum chamber, the water injection device corresponds in position to the water injection station and is configured to inject water into the upper cover;
a lower cover loading device installed inside the vacuum chamber, the lower cover loading device corresponds in position to the lower cover loading station and is configured to move a lower cover onto the upper cover;
a welding head installed inside the vacuum chamber, the welding head corresponds in position to the welding station and is configured to weld the upper cover and the lower cover; and
an unloading device installed inside the vacuum chamber, the unloading device corresponds in position to the unloading station and is configured to unload the vapor chamber.

2. The assembly equipment for the vapor chamber according to claim 1, further comprising a compression device, the compression device is configured to press the upper cover and the lower cover together, wherein the compression device comprises a first telescopic part, a mounting plate, a link rod, a first pressure plate, and a second pressure plate, the first pressure plate and the second pressure plate are both fixed to the mounting plate via the link rod, the first pressure plate is annular and is sleeved on the second pressure plate with an annular gap between the first pressure plate and the second pressure plate, the annular gap is adapted to the vapor chamber, and the welding head is mounted on the mounting plate and configured to weld the upper cover and the lower cover through the annular gap.

3. The assembly equipment for the vapor chamber according to claim 1, further comprising a plurality of material holders for placing the upper cover, wherein the plurality of material holders are all fixedly connected to the turnplate, and the upper cover loading station, the water injection station, the lower cover loading station, the welding station, and the unloading station each are provided with one of the plurality of material holders.

4. The assembly equipment for the vapor chamber according to claim 3, wherein each of the plurality of material holders is fixedly connected with a plurality of positioning blocks, and the plurality of positioning blocks are circumferentially distributed and are configured to limit a movement of the upper cover.

5. The assembly equipment for the vapor chamber according to claim 4, wherein surfaces of the plurality of positioning blocks facing each other are formed with arc-shaped surfaces.

6. The assembly equipment for the vapor chamber according to claim 1, wherein the upper cover loading device comprises a placement plate fixedly installed in the vacuum chamber, a plurality of positioning posts fixedly connected with the placement plate, a second telescopic part fixedly connected with the placement plate, and a first robotic arm mounted in the vacuum chamber, the plurality of positioning posts are circumferentially distributed on the placement plate and configured to limit a movement of the upper cover, the second telescopic part is configured to push the upper cover upward, and the first robotic arm is configured to transport the upper cover to the upper cover loading station.

7. The assembly equipment for the vapor chamber according to claim 6, wherein the first robotic arm comprises a frame fixedly installed in the vacuum chamber, a linear guide rail fixedly installed on the frame, a third telescopic part fixedly connected to an output end of the linear guide rail, and a suction cup, and the suction cup is fixedly attached to the third telescopic part and is configured to adsorb the upper cover.

8. The assembly equipment for the vapor chamber according to claim 1, wherein the unloading device comprises a second robotic arm and an unloading base, the unloading base is configured with a plurality of slots for accommodating the vapor chamber, and the second robotic arm is fixedly mounted inside the vacuum chamber and is configured to transfer the vapor chamber into a respective one of the plurality of slots.

9. A manufacturing process for a vapor chamber by using the assembly equipment for the vapor chamber according to claim 1, comprising:
S1: manufacturing the upper cover and the lower cover;
S2: manufacturing the copper mesh and welding the copper mesh into the upper cover;
S3: placing a plurality of upper covers welded with copper meshes onto the upper cover loading device;
S4: evacuating the vacuum chamber to create the vacuum environment;
S5: transferring one of the plurality of upper covers welded with the copper meshes on the upper cover loading device to the water injection station, to fill the one of the plurality of upper covers with the water;
S6: moving the one of the plurality of upper covers to the lower cover loading station, then moving the lower cover onto the one of the plurality of upper covers to be in contact with the one of the plurality of upper covers;
S7: welding the one of the plurality of upper covers and the lower cover in contact with one of the plurality of upper covers; and
S8: unloading the vapor chamber.
